(19) United States
(12) Patent Application Publication
(10) Pub. No.: US 2024/0039058 A1
(43) Pub. Date: Feb. 1, 2024

(54) BATTERY PACK, ELECTRIC TOOL AND CHARGING DEVICE

(71) Applicant: NINGBO DAYE GARDEN MACHINERY CO., LTD, Yuyao (CN)

(72) Inventors: Xiaobo Ye, Yuyao (CN); Wenming Wu, Yuyao (CN); Huaide Chen, Yuyao (CN); Lijun Peng, Yuyao (CN); Yunbo Yang, Yuyao (CN); Qian Ding, Yuyao (CN)

(21) Appl. No.: 18/085,613

(22) Filed: Dec. 21, 2022

(30) Foreign Application Priority Data
Jul. 29, 2022 (CN) 202222028057.5
Sep. 30, 2022 (CN) 202211208000.1

(51) Int. Cl. H01M 10/42; G01R 31/36; H01M 10/48; H01M 50/247

(52) U.S. Cl. CPC H01M 10/425; G01R 31/3646; H01M 10/488; H01M 50/247; H01M 2220/30; H01M 50/262

(57) ABSTRACT

The present disclosure provides a battery pack, an electric tool, and a charging device. The battery pack comprising a housing having a connecting portion configured to match and connect to a tool or a charging device, wherein the connecting portion comprises a first connecting terminal, a second connecting terminal, a third connecting terminal, a fourth connecting terminal, a fifth connecting terminal, and a sixth connecting terminal; a first battery cell group and a second battery cell group are disposed in the housing, and a quantity of battery cells electrically connected in series in the first battery cell group is equal to a quantity of battery cells electrically connected in series in the second battery cell group; wherein the first battery cell group has a first positive terminal and a first negative terminal, and the second battery cell group has a second positive terminal and a second negative terminal; wherein the first positive terminal, the first negative terminal, the second positive terminal and the second negative terminal match and correspondingly connect to the second connecting terminal to the fifth connecting terminal, respectively; wherein the sixth connecting terminal functioning as a signal terminal is electrically connected to a control module disposed in the housing; and wherein the first connecting terminal functioning as a charging terminal is electrically connected to a first end of a switch, a second end of the switch is electrically connected to the first positive terminal, and a third end of the switch is electrically connected to the control module. The battery pack can externally output two voltages by changing input/output connection lines matching the six connecting terminals.

### CROSS-REFERENCE TO RELATED APPLICATIONS

The present application claims a priority of the following Chinese Patent Applications: CN 202222028057.5 filed on Jul. 29, 2022 and CN 202211208000.1 filed on Sep. 30, 2022, the disclosures of which are incorporated herein in their entirety by reference.

### BACKGROUND

### Technical Field

The present disclosure relates to a field of a battery pack, and more particularly to a battery pack, electric tools with battery packs, and charging device applied with battery packs.

### Related Art

Electric tools are gradually driven by storage batteries using secondary batteries such as lithium ion batteries. Storage batteries are each configured to be detachable from an electric tool body. If a voltage drops due to discharge, the storage battery is removed from the electric tool body and charged by an external charging device. Different types of electric tools often have different requirements for voltage and current, and a battery pack with a single voltage cannot supply power for different types of electric tools. Battery packs with different voltage platforms need to be designed to meet requirements of electric tools with different voltages.

For a user, when electric tools with two voltages are used, matching storage batteries/battery packs are required. For some high-power electric tools, power consumption is very fast. Therefore, it is required to prepare more corresponding battery packs, which increases a burden on the user virtually.

Therefore, existing battery packs need to be improved to broaden application scenarios thereof.

### SUMMARY

A number of embodiments of the present disclosure are described herein in summary. However, the vocabulary expression of the present disclosure is only used to describe some embodiments (whether or not already in the claims) disclosed in this specification, rather than a complete description of all possible embodiments. Some embodiments described above as various features or aspects of the present disclosure may be combined in different ways to form a battery pack or a portion thereof.

In order to solve the problems existing in the prior art, the present disclosure provides a battery pack that externally outputs a voltage by matching an external connecting terminal without using a step-up/step-down voltage conversion circuit. The battery pack comprising a housing having a connecting portion configured to match and connect to a tool or a charging device, wherein the connecting portion comprises a first connecting terminal, a second connecting terminal, a third connecting terminal, a fourth connecting terminal, a fifth connecting terminal, and a sixth connecting terminal; a first battery cell group and a second battery cell group are disposed in the housing, and a quantity of battery cells electrically connected in series in the first battery cell group is equal to a quantity of battery cells electrically connected in series in the second battery cell group; wherein the first battery cell group has a first positive terminal and a first negative terminal, and the second battery cell group has a second positive terminal and a second negative terminal; wherein the first positive terminal, the first negative terminal, the second positive terminal and the second negative terminal match and correspondingly connect to the second connecting terminal to the fifth connecting terminal, respectively; wherein the sixth connecting terminal functioning as a signal terminal is electrically connected to a control module disposed in the housing; and wherein the first connecting terminal functioning as a charging terminal is electrically connected to a first end of a switch, a second end of the switch is electrically connected to the first positive terminal, and a third end of the switch is electrically connected to the control module.

Preferably, a quantity of battery cells in the first battery cell group or the second battery cell group is greater than or equal to 1.

Preferably, the switch is an electrically controlled switch.

Preferably, the electrically controlled switch is one of an MOSFET, an IGBT, a relay, a silicon controlled rectifier, a transistor, or a thyristor.

Preferably, the connecting portion is integrally formed with a part of the housing.

Preferably, the battery pack further comprises a mounting portion disposed on a side of the battery pack, the connecting portion is arranged on a side of the mounting portion, and the mounting portion is configured to match and connect to the tool or the charging device.

Preferably, the battery pack further comprises a display portion disposed on the housing, wherein the display portion is electrically connected to the control module, which triggers the display portion to display an electric quantity of the first battery cell group and/or the second battery cell group.

Preferably, the battery pack further comprises a trigger button arranged on the housing and electrically connected to the control module, wherein the display portion displays the electric quantity of the first battery cell group and/or the second battery cell group when the trigger button is pressed.

In order to solve the problems existing in the prior art, the present disclosure further provides a charging device for charging the battery pack. The charging device comprises external corresponding terminals matching the connecting terminals respectively, and two of the external corresponding terminals are configured to be electrically connected to the second positive terminal and the first negative terminal respectively, and electrically connect the second positive terminal to the first negative terminal, or
two of the external corresponding terminals are configured to be electrically connected to the first positive terminal and the second positive terminal respectively, and electrically connect the first positive terminal to the second positive terminal, the other two of the external corresponding terminals are configured to be electrically connected to the first negative terminal and the second negative terminal respectively, and electrically connect the first negative terminal to the second negative terminal.

In order to solve the problems existing in the prior art, the present disclosure further provides an electric tool carrying the battery pack. The electric tool performs discharge control on the battery pack.

Compared with the prior art, the battery pack of the present disclosure can externally output two voltages by changing input/output connection lines matching the six connecting terminals.

On the advantages and the spirit of the present disclosure, it can be understood further by the following invention descriptions and attached drawings.

### BRIEF DESCRIPTION OF THE DRAWINGS

In order to more clearly explain the embodiment of the present disclosure or the technical scheme in the prior art, the following will briefly introduce the attached drawings that need to be used in the embodiment. It is obvious that the attached drawings in the following description are only some embodiments of the present disclosure. For ordinary technicians in the art, without paying creative labor, other drawings can also be obtained from these drawings.

FIG. 1 illustrates a schematic diagram of a topological structure of a battery pack according to an embodiment of the present disclosure.

FIG. 2 illustrates a schematic diagram of a topological structure of five battery cells in a battery cell group in a battery pack according to an embodiment of the present disclosure.

FIG. 3 illustrates a schematic diagram of a topological structure of four battery cells in a battery cell group in a battery pack according to an embodiment of the present disclosure.

FIG. 4 illustrates a schematic diagram of functional topology of connection between a battery pack and a charger according to an embodiment of the present disclosure.

FIG. 5 illustrates a schematic diagram of functional topology of connection between a battery pack and another charger according to an embodiment of the present disclosure.

FIG. 6 illustrates a schematic diagram of functional topology of connection between a battery pack and a tool according to an embodiment of the present disclosure.

FIG. 7 illustrates a schematic diagram of functional topology of connection between a battery pack and another tool according to an embodiment of the present disclosure.

FIG. 8 illustrates a schematic diagram of a topological structure of a battery pack according to another embodiment of the present disclosure.

FIG. 9 illustrates a schematic top structural view of a battery pack according to an embodiment of the present disclosure.

### DETAILED DESCRIPTION

The foregoing solutions are further described below with reference to specific embodiments. It should be understood that these embodiments are used to illustrate the present application and are not used to limit the scope of the present application. Implementation conditions adopted in the embodiments can be further adjusted as conditions of specific manufacturers, and implementation conditions not indicated are usually those in routine experiments.

Unless otherwise defined, the technical terms or scientific terms used in the embodiments of the present disclosure shall have the ordinary meanings understood by a person of ordinary skill in the art to which the present application belongs. The words “first”, “second” and similar words used in the embodiments of the present disclosure do not denote any order, quantity, or importance, but are merely used to distinguish between different components. Similar words such as “comprising” or “including” each mean that an element or object appearing before the word covers listed elements or objects and equivalents thereof appearing after the word, without excluding other elements or objects. Words such as “connection” or “connected” are not limited to a physical or mechanical connection, but may include an electrical connection, no matter whether the connection is direct or indirect. Herein, “electrical connection” includes the case where the constituent elements are connected together by elements with a certain electrical function. There is no special limitation on the “element with a certain electrical function” as long as the element can receive and send electrical signals between connected constituent elements. The “element with a certain electrical function” may be, for example, an electrode or an arranged wire, or a switching element such as a transistor, or another functional element such as a resistor, an inductor or a capacitor. “Up”, “down”, “left”, “right”, and the like are only used to indicate a relative positional relationship. When an absolute position of a described object changes, the relative positional relationship may also change accordingly.

In the present disclosure, an orientational or positional relationship indicated by a term such as “upper”, “lower”, “inner”, or “middle” is based on the orientational or positional relationship shown in the accompanying drawings. These terms are mainly intended to better describe the present disclosure and embodiments thereof, and are not intended to limit that the indicated device, element, or component must have a particular orientation, or be constructed and operated in a particular orientation.

The present disclosure provides a battery pack. The battery pack includes a housing, and a switch, a first battery cell group and a second battery cell group disposed in the housing. The housing includes a connecting portion internally provided with six connecting terminals (a first connecting terminal to a sixth connecting terminal), and a quantity of battery cells sequentially electrically connected in series in the first battery cell group is equal to a quantity of battery cells sequentially electrically connected in series in the second battery cell group, that is, the first battery cell group and the second battery cell group have the same voltage.

The first battery cell group has a first positive terminal and a first negative terminal, and the second battery cell group has a second positive terminal and a second negative terminal.

The first positive terminal, the first negative terminal, the second positive terminal and the second negative terminal respectively match and connect to four connecting terminals in the connecting portion (for example, the first positive terminal, the first negative terminal, the second positive terminal and the second negative terminal respectively match and connect to the second connecting terminal to the fifth connecting terminal).

The sixth connecting terminal functioning as a signal terminal is electrically connected to a control module in the housing.

The first connecting terminal functioning as a charging terminal of the battery pack is electrically connected to a first end of the switch, a second end of the switch is electrically connected to the first positive terminal, and a third end (trigger end) of the switch is electrically connected to the control module. If connected to a tool during use, the six connecting terminals of the battery pack are connected by matched external corresponding terminals of connection ends of the tool, and the second connecting terminal 2 is short-circuited with the third connecting terminal 3 and/or the second connecting terminal 2 is short-circuited with the fourth connecting terminal 4, to implement switching of series connection or parallel connection between the first battery cell group and the second battery cell group (without the aid of an electronic conversion circuit, to reduce control complexity and costs), so that the battery pack can externally output two voltages (high voltage/low voltage), thereby meeting voltage requirements of different tools.

Next, the battery pack according to the present disclosure is described with reference to the accompanying drawings.

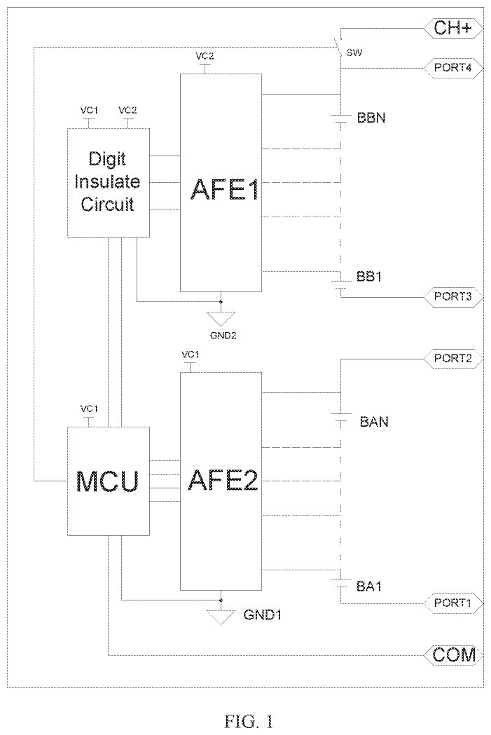

FIG. 1 illustrates a schematic diagram of a topological structure of a battery pack according to an embodiment of the present disclosure.

The battery pack includes a first battery cell group and a second battery cell group, and each battery cell group includes at least one battery cell electrically connected in series.

The first battery cell group has a first positive terminal PORT4 and a first negative terminal PORT3, that is, in the first battery cell group, a negative terminal of a battery cell with a minimum potential is electrically connected to the first negative terminal PORT3, and a positive terminal of a battery cell with a maximum potential is connected to the first positive terminal PORT4.

The second battery cell group has a second positive terminal PORT2 and a second negative terminal PORT1, which match and electrically connect to the connecting portion. That is, in the second battery cell group, a negative terminal of a battery cell with a minimum potential is electrically connected to the second negative terminal PORT1, and a positive terminal of a battery cell with a maximum potential is connected to the second positive terminal PORT2.

A first control unit AFE1 is provided with a plurality of sampling ports, and each sampling port is electrically connected to a matching and corresponding battery cell in the first battery cell group by using a sensor.

A second control unit AFE2 is provided with a plurality of sampling ports, and each sampling port is electrically connected to a matching and corresponding battery cell in the first battery cell group by using a sensor.

A charging port CH+ electrically connected to the first connecting terminal is electrically connected to a first end of the switch SW, a second end of the switch SW is electrically connected to the first positive terminal, and a third end (trigger end) of the switch SW is electrically connected to a control module MCU. In this embodiment, in each battery cell group, one or more battery cells are provided and are connected in series. The battery cell groups have the same voltage. In some embodiments, each battery cell group may include two branches as shown in FIG. 8. The embodiment shown in FIG. 8 differs from the embodiment shown in FIG. 1 in that each battery cell group may include two branches (also referred to as two branches connected in parallel, where in the first battery cell group, the branch where battery cells BB1 and BBN are located is electrically connected in parallel to the branch where battery cells CB1 and CBN are located; and in the second battery cell group, the branch where battery cells BA1 and BAN are located is electrically connected in parallel to the branch where battery cells CA1 and CAN are located) or more branches connected in parallel, with each branch having one or more battery cells.

Mode 1:

Through insertion of external corresponding terminals (not shown in the figure), a controller of an external charger or a tool short-circuits PORT2 and PORT3, so that the first battery cell group and the second battery cell group are electrically connected in series, and a first voltage for external output or input is obtained between PORT1 and PORT4.

Mode 2:

Through insertion of external corresponding terminals (not shown in the figure), a controller of an external charger or a tool short-circuits PORT2 and PORT4, and short-circuits PORT1 and PORT3, so that a second voltage for external output or input is obtained between PORT4 and PORT1.

In this way, no step-up or step-down conversion circuit or device is disposed in the battery pack, and only by inserting external corresponding terminals (the external corresponding terminals are disposed in the charger or discharge controller) into the connecting terminals disposed on the housing, an open/short circuit change of the two battery cell groups in the battery pack is completed, thereby implementing switching between the first battery cell group and the second battery cell group (series connection or parallel connection) to externally output two voltages.

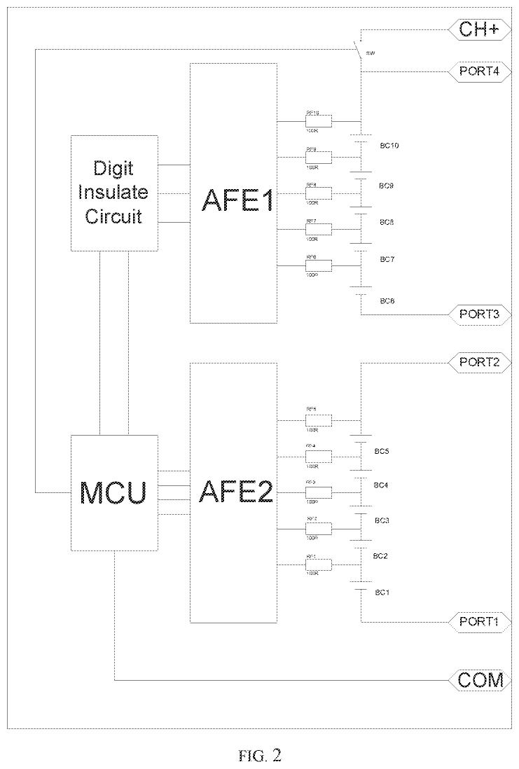

In some embodiments, each battery cell group includes five battery cells electrically connected in series, as shown in FIG. 2. Switching between the first battery cell group and the second battery cell group (series connection or parallel connection) is implemented to externally output two voltages (20 V/40 V).

A first control unit AFE1 is provided with five sampling ports, and each sampling port is electrically connected to a matching and corresponding battery cell in the first battery cell group by using a sensor. For example, one sampling port is electrically connected to a battery cell BC6 by using a sensor RF6, one sampling port is electrically connected to a battery cell BC7 by using a sensor RF7, one sampling port is electrically connected to a battery cell BC8 by using a sensor RF8, one sampling port is electrically connected to a battery cell BC9 by using a sensor RF9, and one sampling port is electrically connected to a battery cell BC10 by using a sensor RF10. The first control unit AFE1 is electrically connected to a control module MCU by using a conversion unit. A negative terminal of the battery cell BC6 is electrically connected to the first negative terminal PORT3, and the battery cell BC10 is electrically connected to the first positive terminal PORT4.

A second control unit AFE2 is provided with five sampling ports, and each sampling port is electrically connected to a matching and corresponding battery cell in the first battery cell group by using a sensor. For example, one sampling port is electrically connected to a battery cell BC1 by using a sensor RF1, one sampling port is electrically connected to a battery cell BC2 by using a sensor RF2, one sampling port is electrically connected to a battery cell BC3 by using a sensor RF3, one sampling port is electrically connected to a battery cell BC4 by using a sensor RF4, and one sampling port is electrically connected to a battery cell BC5 by using a sensor RF5. The second control unit AFE2 is electrically connected to the control module MCU. A negative terminal of the battery cell BC1 is electrically connected to the second negative terminal PORT1, and the battery cell BC5 is electrically connected to the second positive terminal PORT2. In another implementation, each battery cell group may include two or more branches connected in series and parallel, with each branch having five battery cells.

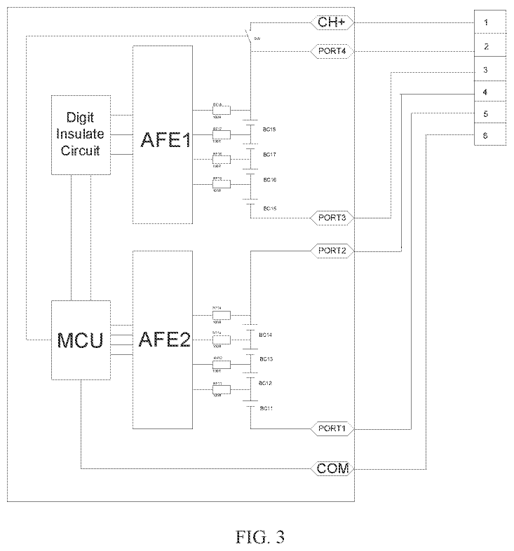

In some embodiments, four battery cells of each battery cell group that may be electrically connected in series are shown in FIG. 3.

The battery pack includes a first battery cell group and a second battery cell group, and each battery cell group includes four battery cells electrically connected in series.

The first battery cell group has a first positive terminal PORT4 and a first negative terminal PORT3. The first positive terminal PORT4 is electrically connected to a second connecting terminal 2 of the connecting portion, and the first negative terminal PORT3 is electrically connected to a third connecting terminal 3 of the connecting portion.

The second battery cell group has a second positive terminal PORT2 and a second negative terminal PORT1. The second positive terminal PORT2 is electrically connected to a fourth connecting terminal 4 of the connecting portion, and the second negative terminal PORT1 is electrically connected to a fifth connecting terminal 5 of the connecting portion.

A first control unit AFE1 includes four sampling ports, and each sampling port is electrically connected to a matching and corresponding battery cell in the first battery cell group by using a sensor. For example, one sampling port is electrically connected to a battery cell BC15 by using a sensor RF15, one sampling port is electrically connected to a battery cell BC16 by using a sensor RF16, one sampling port is electrically connected to a battery cell BC17 by using a sensor RF17, and one sampling port is electrically connected to a battery cell BC18 by using a sensor RF18. The first control unit AFE1 is electrically connected to the control module MCU by using a conversion unit, such as a digit insulate circuit shown in FIG. 1 to FIG. 3. A negative terminal of the battery cell BC15 is electrically connected to the first negative terminal PORT3, and a positive terminal of the battery cell BC18 is electrically connected to the first positive terminal PORT4.

A second control unit AFE2 includes four sampling ports, and each sampling port is electrically connected to a matching and corresponding battery cell in the first battery cell group by using a sensor. For example, one sampling port is electrically connected to a battery cell BC11 by using a sensor RF11, one sampling port is electrically connected to a battery cell BC12 by using a sensor RF12, one sampling port is electrically connected to a battery cell BC13 by using a sensor RF13, and one sampling port is electrically connected to a battery cell BC14 by using a sensor RF14. The second control unit AFE2 is electrically connected to the control module MCU through the digit insulate circuit. A negative terminal of the battery cell BC11 is electrically connected to the second negative terminal PORT1, and a positive terminal of the battery cell BC14 is electrically connected to the second positive terminal PORT2.

A charging port CH+ electrically connected to the first connecting terminal 1 is electrically connected to a first end of a switch SW, a second end of the switch SW is electrically connected to the first positive terminal PORT4, and a third end (trigger end) of the switch SW is electrically connected to a control module MCU. The battery pack can externally output two voltages of 16 V/32 V.

Mode 1:

Through insertion of external corresponding terminals arranged on a tool, the second connecting terminal 2 and the third connecting terminal 3 are short-circuited to short-circuit PORT2 and PORT3, so that a high voltage output is obtained between PORT4 and PORT1 (the first battery cell group and the second battery cell group are connected in series), and the battery pack externally outputs a voltage of 32 V.

Mode 2:

Through insertion of external corresponding terminals arranged on a tool, the second connecting terminal 2 and the fourth connecting terminal 4 are short-circuited to short-circuit PORT2 and PORT4, and the first connecting terminal 1 and the third connecting terminal 3 are short-circuited to short-circuit PORT1 and PORT3, so that a low voltage output is obtained between PORT4 and PORT1 (the first battery cell group and the second battery cell group are connected in parallel), and the battery pack externally outputs a voltage of 16 V.

In some embodiments, six battery cells may be provided in each battery cell group, and the battery pack can externally output two voltages of 24 V/48 V. Seven battery cells may be provided in each battery cell group, and the battery pack can externally output two voltages of 28 V/56 V. Eight battery cells may be provided in each battery cell group, and the battery pack can externally output two voltages of 32 V/64 V. Nine battery cells may be provided in each battery cell group, and the battery pack can externally output two voltages of 36 V/72 V. Ten battery cells may be provided in each battery cell group, and the battery pack can externally output two voltages of 40 V/80 V, and the like.

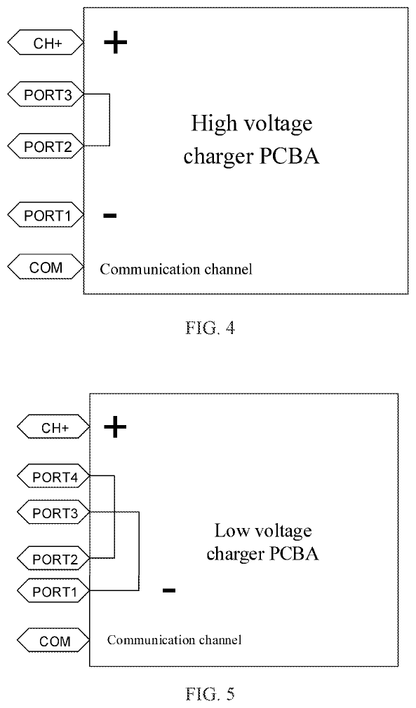

Through this design of the embodiments mentioned above, two voltages can be externally output by connecting matching external corresponding terminals with substantially no increase in cost of the battery pack. It can be understood that in this case, when the battery pack is being charged, a requirement for charging of the battery pack can be met by matching adjustment on terminals of a charger. With a battery pack which can externally output a voltage of 20 V/40 V as an example, the battery pack may be charged by a 20 V matching charger (charging device) or a 40 V matching charger. The charger is provided with external corresponding terminals (for example, six external corresponding terminals) matching connecting terminals respectively, and two external corresponding terminals are configured to be electrically connected to a second positive terminal and a first negative terminal respectively, and electrically connect the second positive terminal to the first negative terminal (by using a preset jumper), with a schematic function diagram of the connection shown in FIG. 4, or two external corresponding terminals are configured to be electrically connected to a first positive terminal and a second positive terminal respectively, and electrically connect the first positive terminal to the second positive terminal, and two external corresponding terminals are configured to be electrically connected to a first negative terminal and a second negative terminal respectively, and electrically connect the first negative terminal to the second negative terminal, with a schematic function diagram of the connection shown in FIG. 5. FIG. 4 shows a schematic connection between a high voltage charger and a battery pack, and FIG. 5 shows a schematic connection between a low voltage charger and a battery pack.

This broadens the application range of the battery pack. An example in which a battery pack externally outputs a voltage of 20 V/40 V is taken for description.

A voltage platform of a normal hand-held portable electric tool is substantially 20 V, so that by using a corresponding terminal jumper of a battery mounting portion of the portable electric tool (this design substantially does not increase design costs, and for the connection method, refer to the external corresponding terminals of the charger), the battery pack can operate in mode 2, and an operation time can be further prolonged by connecting two groups of battery cells in parallel (equivalent to configuring two battery packs).

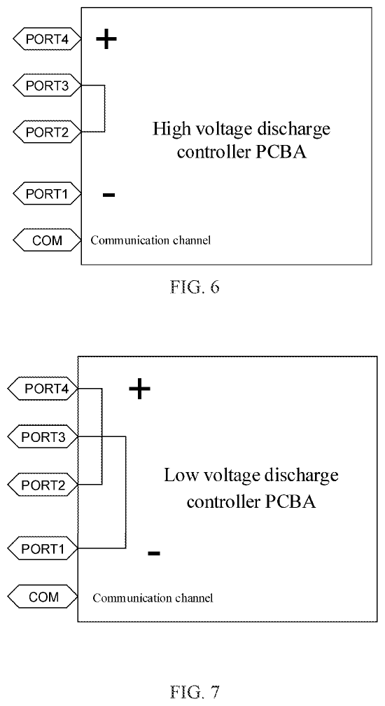

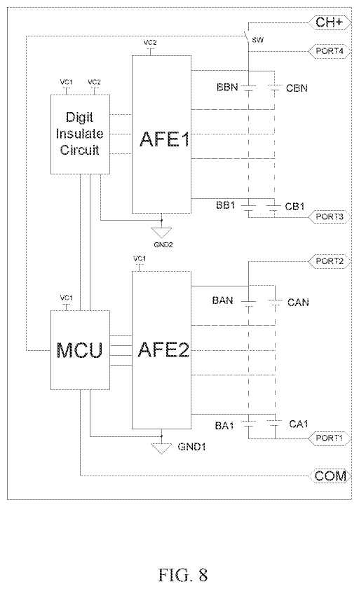

If the battery pack is applied to a tool with a high-voltage platform (such as a cutting circular saw and a DIY hammer drill), the battery pack can operate in mode 1 by changing wiring of corresponding terminals of a battery mounting portion on the tool (this design substantially does not increase design costs). In this way, one battery pack can be used for tools with two voltage platforms (schematic function diagrams of the connections are shown in FIG. 6 and FIG. 7. FIG. 6 shows a schematic connection between a high-voltage discharge controller of a tool and a battery pack (two external corresponding terminals of the tool electrically connect PORT2 and PORT3 to short-circuit PORT2 and PORT3). FIG. 7 shows a schematic connection between a low-voltage discharge controller of a tool and a battery pack (two external corresponding terminals of the tool electrically connect PORT2 and PORT4 to short-circuit PORT2 and PORT4, and two external male terminals electrically connect PORT1 and PORT3 to short-circuit PORT1 and PORT3), which substantially covers tools used by users on a daily basis.

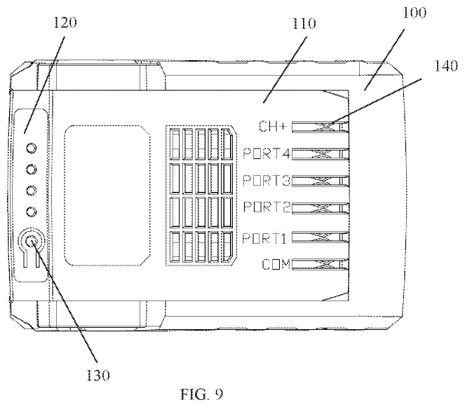

In some embodiments, referring to FIG. 9, a mounting portion 110 is disposed on a side of a housing 100 of the battery pack, a connecting portion 140 having six connecting terminals, CH+, PORT1/PORT2/PORT3/PORT4, and COM (signal terminal) is arranged on a side of the mounting portion 110, and the mounting portion 110 is configured to match and connect to a tool or a charging device (not shown in the figure). After matching and connecting to the tool or the charging device, the connecting portion 140 matches the corresponding portion of the tool or the charging device. In some embodiments, the housing 100 of the battery pack further includes a display portion 120 electrically connected to the control module MCU, which triggers the display portion 120 to display an electric quantity of the first battery cell group and/or the second battery cell group. Preferably, the display portion 120 is a display screen or an indicator. The housing 100 is provided with a button 130. The indicator 120 is turned on by pressing the button 130 on the housing 100, to display the electric quantity of the first battery cell group and/or the second battery cell group.

The foregoing embodiments are only intended to illustrate the technical concept and characteristics of the present disclosure, so that a person skilled in the art can understand the content of the present disclosure and implement the content accordingly, and the embodiments cannot be used to limit the protection scope of the present disclosure. Any equivalent transformation or modification made based on the spirit of the present disclosure should fall within the protection scope of the present disclosure.

What is claimed is:

1. A battery pack, comprising:
a housing having a connecting portion configured to match and connect to a tool or a charging device, wherein the connecting portion comprises a first connecting terminal, a second connecting terminal, a third connecting terminal, a fourth connecting terminal, a fifth connecting terminal, and a sixth connecting terminal;
a first battery cell group and a second battery cell group are disposed in the housing, and a quantity of battery cells electrically connected in series in the first battery cell group is equal to a quantity of battery cells electrically connected in series in the second battery cell group;
wherein the first battery cell group has a first positive terminal and a first negative terminal, and the second battery cell group has a second positive terminal and a second negative terminal;
wherein the first positive terminal, the first negative terminal, the second positive terminal and the second negative terminal match and correspondingly connect to the second connecting terminal to the fifth connecting terminal, respectively;
wherein the sixth connecting terminal functioning as a signal terminal is electrically connected to a control module disposed in the housing; and
wherein the first connecting terminal functioning as a charging terminal is electrically connected to a first end of a switch, a second end of the switch is electrically connected to the first positive terminal, and a third end of the switch is electrically connected to the control module.

2. The battery pack according to claim 1, wherein a quantity of battery cells in the first battery cell group or the second battery cell group is greater than or equal to 1.

3. The battery pack according to claim 1, wherein the switch is an electrically controlled switch.

4. The battery pack according to claim 3, wherein the electrically controlled switch is one of an MOSFET, an IGBT, a relay, a silicon controlled rectifier, a transistor, or a thyristor.

5. The battery pack according to claim 1, wherein the connecting portion is integrally formed with a part of the housing.

6. The battery pack according to claim 1, further comprising a mounting portion disposed on a side of the battery pack, the connecting portion is arranged on a side of the mounting portion, and the mounting portion is configured to match and connect to the tool or the charging device.

7. The battery pack according to claim 1, further comprising a display portion disposed on the housing, wherein the display portion is electrically connected to the control module, which triggers the display portion to display an electric quantity of the first battery cell group and/or the second battery cell group.

8. The battery pack according to claim 7, further comprising a trigger button arranged on the housing and electrically connected to the control module, wherein the display portion displays the electric quantity of the first battery cell group and/or the second battery cell group when the trigger button is pressed.

9. A charging device for charging the battery pack according to claim 1, wherein the charging device comprises external corresponding terminals matching the connecting terminals respectively, and two of the external corresponding terminals are configured to be electrically connected to the second positive terminal and the first negative terminal respectively, and electrically connect the second positive terminal to the first negative terminal, or
two of the external corresponding terminals are configured to be electrically connected to the first positive terminal and the second positive terminal respectively, and electrically connect the first positive terminal to the second positive terminal, the other two of the external corresponding terminals are configured to be electrically connected to the first negative terminal and the second negative terminal respectively, and electrically connect the first negative terminal to the second negative terminal.

10. The charging device for charging the battery pack according to claim 9, wherein a quantity of battery cells in the first battery cell group or the second battery cell group is greater than or equal to 1.

11. The charging device for charging the battery pack according to claim 9, wherein the switch is an electrically controlled switch which is one of an MOSFET, an IGBT, a relay, a silicon controlled rectifier, a transistor, or a thyristor.

12. The charging device for charging the battery pack according to claim 9, wherein the connecting portion is integrally formed with a part of the housing.

13. The charging device for charging the battery pack according to claim 9, further comprising a mounting portion disposed on a side of the battery pack, the connecting portion is arranged on a side of the mounting portion, and the mounting portion is configured to match and connect to the tool or the charging device.

14. The charging device for charging the battery pack according to claim 9, further comprising a display portion disposed on the housing, wherein the display portion is electrically connected to the control module, which triggers the display portion to display an electric quantity of the first battery cell group and/or the second battery cell group.

15. The charging device for charging the battery pack according to claim 14, further comprising a trigger button arranged on the housing and electrically connected to the control module, wherein the display portion displays the electric quantity of the first battery cell group and/or the second battery cell group when the trigger button is pressed.

16. An electric tool carrying the battery pack according to claim 1, wherein the electric tool performs discharge control on the battery pack.

17. The electric tool carrying the battery pack according to claim 16, wherein a quantity of battery cells in the first battery cell group or the second battery cell group is greater than or equal to 1.

18. The electric tool carrying the battery pack according to claim 16, wherein the switch is an electrically controlled switch which is one of an MOSFET, an IGBT, a relay, a silicon controlled rectifier, a transistor, or a thyristor.

19. The electric tool carrying the battery pack according to claim 16, further comprising a display portion disposed on the housing, wherein the display portion is electrically connected to the control module, which triggers the display portion to display an electric quantity of the first battery cell group and/or the second battery cell group.

20. The electric tool carrying the battery pack according to claim 16, further comprising a trigger button arranged on the housing and electrically connected to the control module, wherein the display portion displays the electric quantity of the first battery cell group and/or the second battery cell group when the trigger button is pressed.
